(19) United States
(12) Patent Application Publication
(10) Pub. No.: US 2011/0090722 A1
(43) Pub. Date: Apr. 21, 2011

(54) VOLTAGE CONVERTER

(75) Inventor: Leo Warmerdam, Helmond (NL)

(73) Assignee: NXP B.V., Eindhoven (NL)

(21) Appl. No.: 12/999,278

(22) PCT Filed: Jun. 11, 2009
(86) PCT No.: PCT/IB2009/052493

§ 371 Date: Dec. 15, 2010

(30) Foreign Application Priority Data
Jun. 16, 2008 (EP) 08104420.8
Jun. 11, 2009 (IB) PCT/IB2009/052493

(51) Int. Cl. H02M 3/07; H01L 21/50

(52) U.S. Cl. 363/62; 438/108; 257/E21.499

(57) ABSTRACT

A switched capacitor DC-DC voltage converter comprising: a first circuit (21) having a plurality of switches (M1-M4); and a second circuit (22) having a plurality of capacitors (C1, C2, C3), each capacitor connected to one or more of the plurality of switches, wherein the first and second circuits are provided on respective first and second dies on a common substrate.

The invention relates to the field of voltage converters, and in particular to dc-dc converters having switched capacitors.

Switched capacitor DC-DC converters rely on alternately connecting capacitors to a voltage input and output in differing topologies. For example, a switched capacitor converter for reducing a voltage can be configured to charge two capacitors in series and then discharge the capacitors in parallel. This would produce an output voltage of half the input voltage, but at twice the current (minus various inefficiencies). Switched capacitor converters can also be configured to generate higher voltage outputs through various arrangements. Such converters tend to work most efficiently with a reduction factor of 2. Because switched capacitor converters operate on discrete quantities of charge, these are also sometimes referred to as charge pump converters, or simply charge pumps.

Modern charge pumps, for example as described by Phang and Johns in “A 1V 1 mW CMOS Front-End with On-chip Dynamic Gate Biasing for a 75 Mb/s Optical Receiver,” IEEE Int. Solid-State Circ. Conf. Dig. Tech. Papers, pp. 218-219 February 2001, include three or more capacitors connected to a switched input voltage, at least one of the capacitors acting to smooth the output voltage and the others being charged and discharged rapidly by a number of transistors to generate the required voltage.

An example of converter having multiple conversion ratios and integrated on a single die is described by Shao Bin et al in “A Capacitive Step-Down Converter Using a Linear Mode Pre-Regulator for Improved Load Regulation”, 8th International Conference on Solid-State and Integrated Circuit Technology, 2006, pp 1708-1710.

U.S. Pat. No. 6,198,645 discloses a number of different configurations of DC-DC converters using multiple capacitors and switches to enable both up and down voltage conversion with one switched capacitor array.

Integrating the switching circuitry and the capacitors into a single integrated circuit (IC) can be expensive, because a much larger die area is generally required for capacitors compared with transistors. Alternatively, and commonly used in practice, the capacitors can be external discrete components connected to a switching IC package. This solution, however, requires a lot more overall space.

External discrete capacitors can be reduced in size, for example in the form of multilayer ceramic capacitors, and/or the charge/discharge frequency can be increased to compensate for a lower capacitance, but then electromagnetic compatibility (EMC) problems can result from radiation emitted by connections between the IC and the capacitors. Any external capacitors typically need to be handled separately by the use of pick and place machines, resulting in a lower limit in their physical size.

For low power levels, existing dc-dc converters are therefore typically manufactured with a minimum of external discrete capacitors to be cost-effective. A minimal capacitor count leads to significant drops in efficiency when the conversion ratio differs from the ideal conversion ratio of 2:1 or 1:2 with 2 capacitors. Up-converters for generating high voltages (but small currents) have, however, been made, based on specific staggering of diodes and capacitors.

It is an object of the invention to provide an improved switched capacitor voltage converter.

In accordance with a first aspect of the invention there is provided a switched capacitor DC-DC voltage converter comprising:
a first circuit having a plurality of switches; and
a second circuit having a plurality of capacitors, each capacitor connected to one or more of the plurality of switches,
wherein the first and second circuits are provided on respective first and second dies on a common substrate.

In accordance with a second aspect of the invention there is provided a method of fabricating a switched capacitor DC-DC voltage converter, the method comprising:
providing a first die comprising a circuit having a plurality of switches;
providing a second die comprising a circuit having a plurality of capacitors;
affixing the first and second dies on a common substrate; and
connecting each of the plurality of switches with a respective capacitor.

The invention is described by example in further detail below, with reference to the appended drawings in which:

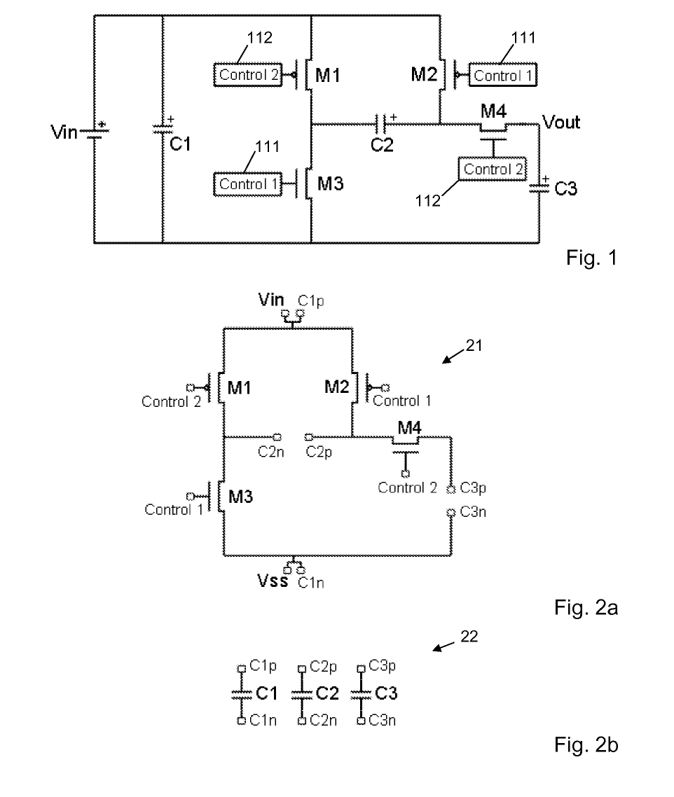

FIG. 1 shows a circuit diagram for an integrated capactive upconverter;

FIG. 2a shows a first circuit having a plurality of control switches; and

FIG. 2b shows a second circuit having a plurality of capacitors connected to the control switches of the first circuit.

Embodiments of the invention use multiple switches, for example in the form of transistors switched by clock pulses, and three or more capacitors to improve the efficiency of the circuit across a range of multiplication factors.

Shown in FIG. 1 is a typical simple implementation of a known capacitive upconverter comprising a plurality of switches M1-M4 and a plurality of capacitors C1-C3, each capacitor being connected to one or more of the plurality of switches. An input voltage Vin is converted to an output voltage Vout by controlled switching of capacitors C2 by control switches M1-M4. Each of the control switches M1-M4 are preferably semiconductor switches, e.g. MOSFETs, operated by clocked signals provided by controllers 111, 112.

FIG. 2a illustrates a first circuit 21 according to the invention, in which the control switches M1-M4, the voltage input Vin and the voltage output Vout connections are provided on a first die. External connections C1n, C1p, C2n, C2p, C3n, C3p are provided to connect to a second circuit 22 comprising capacitors C1, C2, C3 disposed on a separate die, shown in FIG. 2b. The connections between the switches M1-M4 and the respective capacitors C1, C2, C3 may be made for example via wire bonding techniques during assembly of the first and second dies on a common substrate.

By “common substrate”, it is to be understood that the first and second dies are located in fixed relation to one another once brought together, rather than being fabricated by a common processing route. The common substrate is therefore the base on which the dies are fixed, which may for example be a ceramic substrate, a printed circuit board or other suitable base. Connections between the external connections C1n, C1p, C2n, C2p, C3n, C3p on the first die and the capacitors C1, C2, C3 on the second die are preferably made once the first and second dies are fixed in place on the common substrate. Alternatively, the connections may be made before or during affixing the first die relative to the second die, for example by flip-chip bonding or using vias.

Embodiments of the invention also include integration of the switching circuitry on a first (active) die, while the capacitors are provided on a separate second (passive) die. The active and passive dies may be manufactured using differing IC technologies. The passive die may be bigger or smaller than the first die, and can be cheaper to manufacture because process steps and technology requirements are simplified when only passive components are required.

Hence, the invention enables the practical realisation of capacitive DC to DC converter circuits that have multiple capacitors and can improve the efficiency of operation for a range of multiplication factors. Such DC to DC converter circuits can be made both small and efficient.

Because the capacitors are formed on a separate die, a greater number of capacitors can be used to allow for a wider range of input to output conversion ratios, thus addressing the problem of efficiency drops between optimal conversion ratios.

Using passive technology integration for physically small implementations, the passive die containing the capacitors can be embedded in the same IC package as the active die. The fact that the dies are separate can therefore be effectively invisible to the user, who merely has to interface with the converter as an integrated unit.

Because the switching circuit and the capacitors can be arranged in close proximity, high switching frequencies can be used to maximize output power and/or minimize ripple voltage, while keeping EMC issues to a minimum due to the shorter connection lengths in comparison to solutions including off-chip capacitors.

As an example, consider a capacitive dc-dc converter that up-converts an input voltage Vᵢₙ to double its value. Current solutions use 2 external capacitors that are repetitively switched in parallel (to charge the capacitors to the input voltage) and in series (to supply the output at 2Vᵢₙ). This type of converter can function with a high efficiency. However, if the output voltage must vary between Vᵢₙ and 2Vᵢₙ, then the only solution based on this construction is to still put the capacitors in series to 2Vin and then bleed the supply to the intermediate voltage. For a voltage just above Vin, the efficiency drops to about 50%.

With 3 capacitors instead of 2, one could not only make the ratios 1:1 and 2:1 but also 3:2. The higher the number of capacitances therefore, the more connections (and switches in the active die) and variations in the output are possible.

Applying the above solution to off-chip discrete capacitors becomes quickly unacceptable, as every subsequent capacitor added requires more board space, and makes routing between the switching circuit and capacitors progressively more complex.

When the capacitors are provided as a separate die, however, the above limitation is both hidden from the user and the routing problem becomes a standard IC routing issue. Electrical connections between the dies can be made by standard means such as wire bonding or flip-chip techniques. As the length of interconnections between the active die and passive die can be kept to a minimum, the converter can be designed to operate at significantly higher frequencies than traditionally applied in this field: target frequencies could go up to region of hundreds of MHz, to partly compensate for the lower capacitance available using IC technology. The frequency may be determined according to I=f*Q, where I is the output current required and hence an indication of the converted power, f the frequency of operation and Q the charge pumped per cycle.

The above described principles can also be applied to down-converters or combined up-down converters (also known as “buck/boost” converters), where the output voltage can be either higher or lower than the input voltage.

Other variations are also intended to be within the scope of the invention as defined by the appended claims, including the following:
1. some of the capacitors may also be integrated on the active die;
2. the second die comprising the capacitors need not be made using passive technology;
3. the connections between the two dies can be made through bonding, flip-chip, die stacking, via connections or other interconnect means; and
4. there is no necessity for having identical capacitance values, so any ratio of capacitances may in principle to be designed for.

Other embodiments are intentionally within the scope of the invention as defined by the appended claims.

1. A switched capacitor DC-DC voltage converter comprising:
a first circuit having a plurality of switches; and
a second circuit having a plurality of capacitors, each capacitor connected to one or more of the plurality of switches,
wherein the first and second circuits are provided on respective first and second dies on a common substrate.

2. The voltage converter of claim 1 wherein the first and second dies are comprised in a common integrated circuit package.

3. The voltage converter of claim 1 wherein the second die comprises at least three capacitors.

4. The voltage converter of claim 1 wherein the first and second dies are affixed adjacent to each other on the common substrate and connected by wire bonding.

5. The voltage converter of claim 1 wherein the first and second dies are affixed to each other and to the common substrate by flip-chip bonding.

6. The voltage converter of claim 1 wherein the second die comprises only passive components.

7. A method of fabricating a switched capacitor DC-DC voltage converter, the method comprising:
providing a first die comprising a circuit having a plurality of switches;
providing a second die comprising a circuit having a plurality of capacitors;
affixing the first and second dies on a common substrate; and
connecting each of the plurality of switches with a respective capacitor.

8. The method of claim 7 wherein the first and second dies are affixed adjacent to each other on the common substrate and connected by wire bonding.

9. The method of claim 7 wherein the first and second dies are affixed to each other and to the common substrate by flip-chip bonding.

10. The method of claim 7 comprising the step of assembling the first and second dies in a common integrated circuit package.

11. The method of claim 7 wherein the second die comprises at least three capacitors.
